(19) United States
(12) Patent Application Publication
(10) Pub. No.: US 2007/0181957 A1
(43) Pub. Date: Aug. 9, 2007

(54) SEMICONDUCTOR DEVICE HAVING STACKED TRANSISTORS AND METHOD FOR MANUFACTURING THE SAME

(75) Inventors: Sung-Jin KIM, Gyeonggi-do (KR); Seung-Hyun PARK, Seocho-gu (KR); Sang-Jong KIM, Gyeonggi-do (KR); Ryu-Tan CHOI, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/670,946

(22) Filed: Feb. 2, 2007

(30) Foreign Application Priority Data
Feb. 3, 2006 (KR) 2006-10837

(51) Int. Cl. H01L 29/76

(52) U.S. Cl. 257/393

(57) ABSTRACT

Provided is a semiconductor device including a thin film transistor with at least one protruding impurity region and a method for manufacturing the same. The semiconductor device includes bulk transistors formed on a semiconductor substrate and an interlayer insulation layer covering the bulk transistor. At least one thin film transistor is formed on the interlayer insulation layer including impurity regions adjacent thereto. At least one impurity region of the thin film transistor protrudes higher than the other impurity region.

### CROSS-REFERENCE TO RELATED APPLICATIONS

This U.S. non-provisional patent application claims priority under 35 U.S.C. § 119 to Korean Patent No. 10-2006-10837, filed on Feb. 3, 2006, the entire contents of which are hereby incorporated by reference.

### BACKGROUND

1. Technical Field

This disclosure relates to a semiconductor device and a method for manufacturing the same, and more particularly, to a semiconductor device having a stacked transistor and a method for manufacturing the same.

2. Description of the Related Art

Most recent electronic appliances include semiconductor devices. The semiconductor devices include electronic elements such as transistors, resistors, and capacitors. Each electronic element is designed to perform a partial function of the electronic appliances, and is integrated into a semiconductor substrate. For example, an electronic appliance such as a computer or a digital camera includes a semiconductor device such as a memory chip for information storage and a processing chip for information control. The memory chip and the processing chip include the electronic elements integrated on the semiconductor substrate. The semiconductor devices need to be more and more highly integrated to satisfy consumer demands for excellent performance and reasonable price. A semiconductor device having a stacked transistor has been developed to meet these requirements.

FIGS. 1 through 3 are cross-sectional views illustrating a method for manufacturing a conventional semiconductor device having a stacked transistor. For example, the semiconductor device may be a CMOS SRAM having a bulk transistor on a semiconductor substrate and a thin film transistor (TFT) on the bulk transistor.

Referring to FIG. 1, bulk transistors 11 are formed on an active region of a semiconductor substrate 1. The active region is divided by a device isolation layer 3. Each of the bulk transistors 11 includes a gate insulation layer 5, a gate conductive layer 7, an insulation layer pattern 8, a spacer 9, a source region 13, and a drain region 15. The bulk transistors 11 may be a transfer transistor and a drive transistor of an SRAM cell.

A first interlayer insulation layer 19 is formed on a semiconductor substrate 1 having the bulk transistors 11. The first interlayer insulation layer 19 is selectively etched to expose the source regions 13 such that a contact hole is formed. A selective epitaxial growth (SEG) process is performed on the contact hole to form an epitaxial plug 21 in a single crystalline structure. The epitaxial plug 21 serves as a crystallization seed when crystallizing an amorphous silicon thin layer that will be formed later. The amorphous silicon layer (not shown) is deposited on the first interlayer insulation layer 19 to be in contact with the epitaxial plug 21. An etch stop layer 17 may be additionally formed between the semiconductor substrate 1 and the first interlayer insulation layer 19. The amorphous silicon layer is crystallized using a heat treatment process. The crystallized amorphous silicon layer is patterned to form a semiconductor layer pattern 23 for thin film transistor channel formation. The semiconductor layer pattern 23 may be formed of a single crystalline thin layer or a poly crystalline silicon layer having a relatively large size grain. It is important that the semiconductor layer pattern be as close to single crystalline as possible to provide good carrier transport properties in the thin film transistors. Poly crystalline silicon having a large grain size approximates single crystalline silicon on the scale of the channel regions of the thin film transistors.

Referring to FIG. 2, thin film transistors 31 are formed on the semiconductor layer pattern 23. The thin film transistors 31 include a gate insulation layer 25, a gate electrode 27, an insulation pattern 28, a spacer 29, a source region 35, and a drain region 33. The thin film transistors 31 may be load transistors of an SRAM cell.

Referring to FIG. 3, a second interlayer insulation layer 37 is formed on the semiconductor substrate 1. A contact hole is formed to penetrate a portion of the second interlayer insulation layer 37, the semiconductor layer pattern 23, and the epitaxial plug 21. Thus, the source region 13 is exposed. A node contact metal plug 39 is formed to fill the contact hole. The node contact metal plug 39 contacts the bulk transistors 11 and the thin film transistors 31.

The semiconductor device may be a non-volatile memory. In this case, the gate insulation layers 5 and 25 may include charge trap layers. The gate electrodes 7 and 27 may include stacked layers such as a floating gate electrode, a gate interlayer dielectric layer, and a control gate electrode. The bulk transistors 11 and the thin film transistors 31 may be non-volatile memory transistors.

The following problems exist in a method for manufacturing a conventional semiconductor device having a stacked transistor.

Referring to FIGS. 4A and 4B, the thin film transistor 31 is formed on a body layer (i.e., the semiconductor layer pattern 23). A heat treatment process is performed on an amorphous silicon layer 22 at a high temperature for an extended period of time. The semiconductor layer pattern 23 for channel formation is crystallized using the epitaxial plug 21 as a seed. Since the epitaxial plug 21 is acting as a seed, the crystallization process proceeds outwardly from the epitaxial plug 21 along the arrow direction shown in FIG. 4A. However, while performing the heat treatment process, silicon atoms from the amorphous silicon layer 22 may move (or diffuse) toward the region of the epitaxial plug 21 having an excellent crystallization. Accordingly, the silicon atoms may be consumed in the semiconductor layer pattern 23 for channel formation such that a specific region may experience thinning or be completely cut-off as shown at A of FIG. 4B. Additionally, when the contact region of the amorphous silicon layer 22 and the epitaxial plug 21 becomes larger, the crystallization in the amorphous silicon layer 22 can be improved. However, there is a limitation on the crystallization improvement that can be realized in a conventional structure due to the small contact area between the epitaxial plug and the amorphous silicon layer.

Referring to FIG. 5, although initially there is no cutting or thinning in the semiconductor layer pattern 23, a barrier metal 39 of the node contact metal plug 39, i.e., titanium, may cause silicon sucking of the semiconductor layer pattern 23. Accordingly, cutting or thinning (as shown at B) in the semiconductor layer pattern 23 can occur. Additionally, the interface resistance between the semiconductor layer pattern 23 and the node contact metal plug 39 may increase due to incorporation of silicon into the node contact metal plug forming a silicide. Increased interface resistance can lead to degraded or unpredictable operational characteristics of the semiconductor device. FIG. 6 is a scanning electron microscope (SEM) view of cutting (as shown at C) in the semiconductor layer pattern 23 of a conventional device, as described above.

The above problems occur frequently in the conventional stacked transistor process because the thickness of the semiconductor layer pattern for channel formation needs to be thin in order to minimize the leakage current of the stacked thin film transistor. Therefore, the reliability of the semiconductor device deteriorates. The invention addresses these and other problems with the conventional art.

### SUMMARY OF THE INVENTION

The invention provides a semiconductor device having a reliability-improved stacked transistor. The invention also provides a method for manufacturing a semiconductor device having a reliability-improved stacked transistor.

### BRIEF DESCRIPTION OF THE FIGURES

Non-limiting and non-exhaustive embodiments of the invention will be described with reference to the following figures, wherein like reference numerals refer to like parts throughout the various figures unless otherwise specified. In the figures:

FIGS. 1 through 3 are cross-sectional views illustrating a method for manufacturing a conventional semiconductor device having a stacked transistor;

FIG. 4A is a schematic view of a semiconductor layer pattern showing the crystallization direction;

FIG. 4B is a schematic view of a semiconductor layer pattern showing thinning or cutting of the layer;

FIG. 5 is a cross-sectional view of a stacked transistor having thinning in the semiconductor layer pattern;

FIG. 6 is an SEM image of a conventional stacked transistor structure showing cutting of the semiconductor layer pattern;

FIGS. 7 through 11 are cross-sectional views illustrating a method of manufacturing a semiconductor device having a stacked transistor according to a first embodiment of the invention;

FIG. 12 is a cross-sectional view of a modified first embodiment;

FIG. 13 is a cross-sectional view illustrating a method of manufacturing a semiconductor device having a stacked transistor according to a second embodiment of the invention;

FIG. 14 is a cross-sectional view illustrating a method of manufacturing a semiconductor device having a stacked transistor according to a third embodiment of the invention; and

FIG. 15 is a cross-sectional view illustrating a method of manufacturing a semiconductor device having a stacked transistor according to a fourth embodiment of the invention.

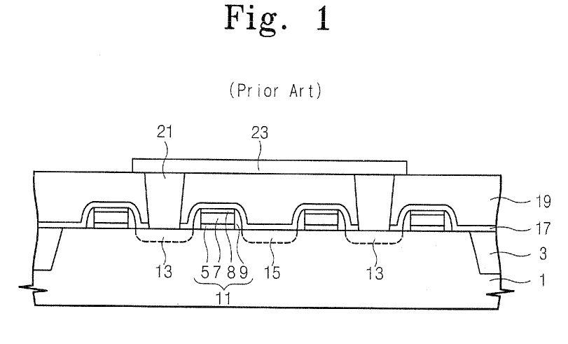

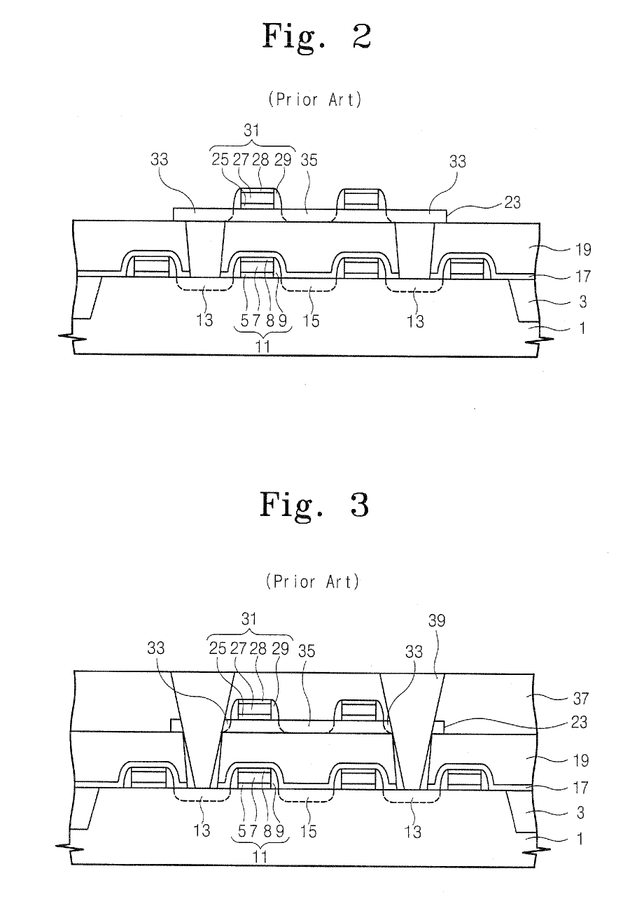

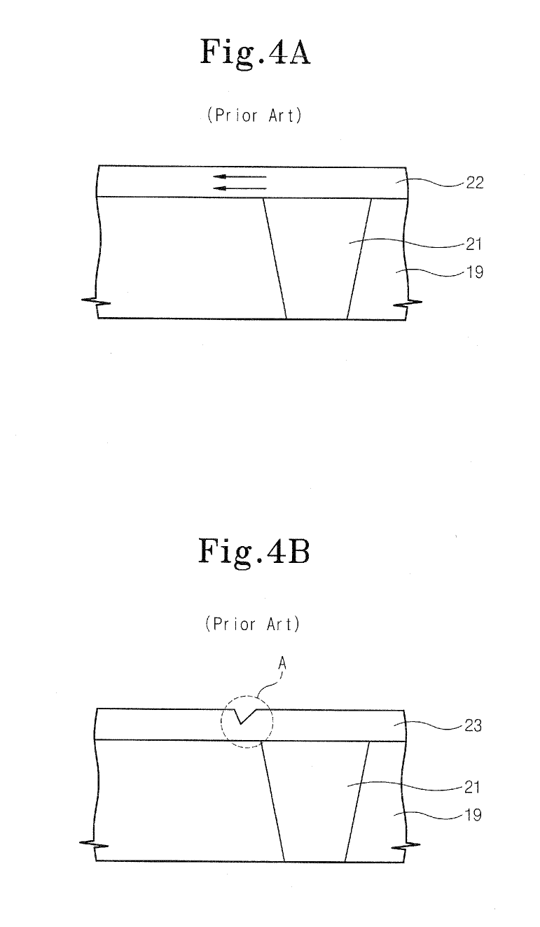

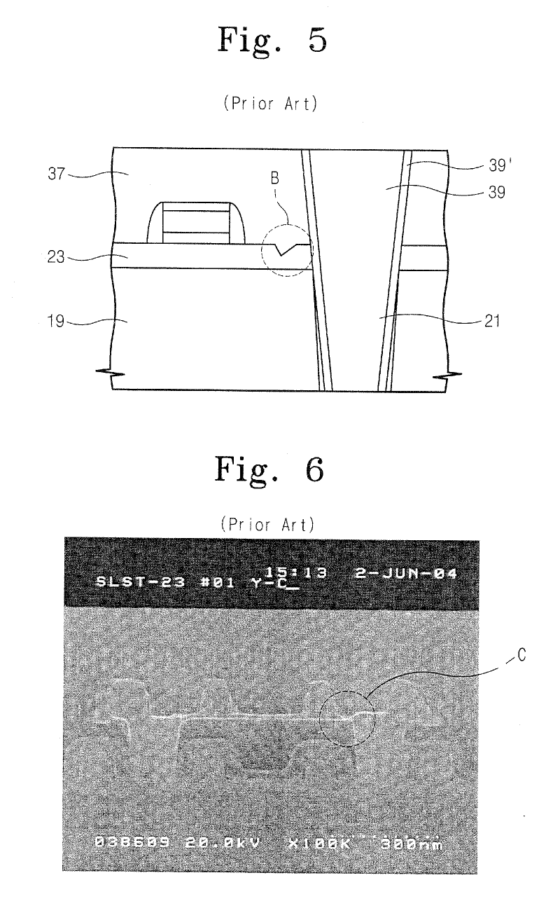

### DETAILED DESCRIPTION

Preferred embodiments of the invention will be described below in more detail with reference to the accompanying drawings. The invention may, however, be embodied in different forms and should not be constructed as limited to the embodiments set forth herein. Rather, these embodiments are provided so that this disclosure will be thorough and complete, and will fully convey the scope of the invention to those skilled in the art. In the figures, the dimensions of layers and regions are exaggerated for clarity of illustration. It will also be understood that when a layer (or film) is referred to as being ‘on’ another layer or substrate, it can be directly on the other layer or substrate, or intervening layers may also be present.

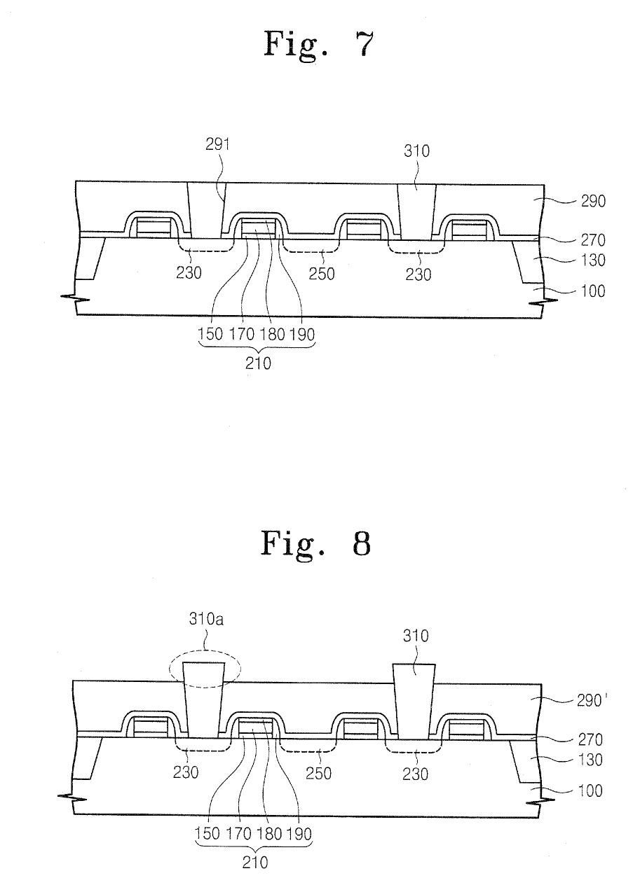

FIGS. 7 through 11 are cross-sectional views illustrating a method of manufacturing a semiconductor device having a stacked transistor according to a first embodiment of the invention.

Referring to FIG. 7, bulk transistors 210 are formed on an active region of a semiconductor substrate 100. The active region is divided by a device isolation layer 130. The bulk transistor 210 may include a gate insulation layer 150, a gate conductive layer 170, an insulation layer pattern 180, a spacer 190, a source region 230, and a drain region 250. The source regions 230 and drain regions 250 may be referred to as impurity regions.

A first interlayer insulation layer 290 is formed on the semiconductor substrate 100. The first interlayer insulation layer 290 is selectively etched to expose the source region 230 such that a contact hole 291 is formed. An epitaxial plug 310 having a single crystalline structure is formed to fill the contact hole 291 using a selective epitaxial growth (SEG) process. The epitaxial plugs 310 may be disposed on opposite impurity regions 230 of the bulk transistors 210, as shown in FIG. 7. In other words, an epitaxial plug 310 may be formed on a source region 230 of one bulk transistor 210 and another epitaxial plug 310 may be formed on a source region of an adjacent bulk transistor 210. Before forming the first interlayer insulation layer 290, an etch stop layer 270 may be additionally formed to protect impurity regions during the etching process for forming the contact hole 291.

Referring to FIG. 8, the first interlayer insulation layer 290 is recessed to be a first interlayer insulation layer pattern 290′ and to form a protruding top region 310a of the epitaxial plug 310. The recessing process may be performed by a wet or dry etching process on the first interlayer insulation layer 290. The height of the protruding top region 310a may be adjusted according to the type of semiconductor devices being manufactured. For example, the height of the protruding top region 310a may be about 250 Å. A sacrificial layer having an etch rate different from that of the first interlayer insulation layer 290 may additionally be formed on the first interlayer insulation layer 290. The sacrificial layer is removed during the recessing process such that a stable process can be performed. Accordingly, the protruding height may depend on the thickness of the sacrificial layer, and can be maintained uniformly. When the first interlayer insulation layer 290 is a silicon oxide layer, the sacrificial layer may be one selected from the group consisting of a silicon nitride layer, a silicon oxide nitride layer, and a combination thereof.

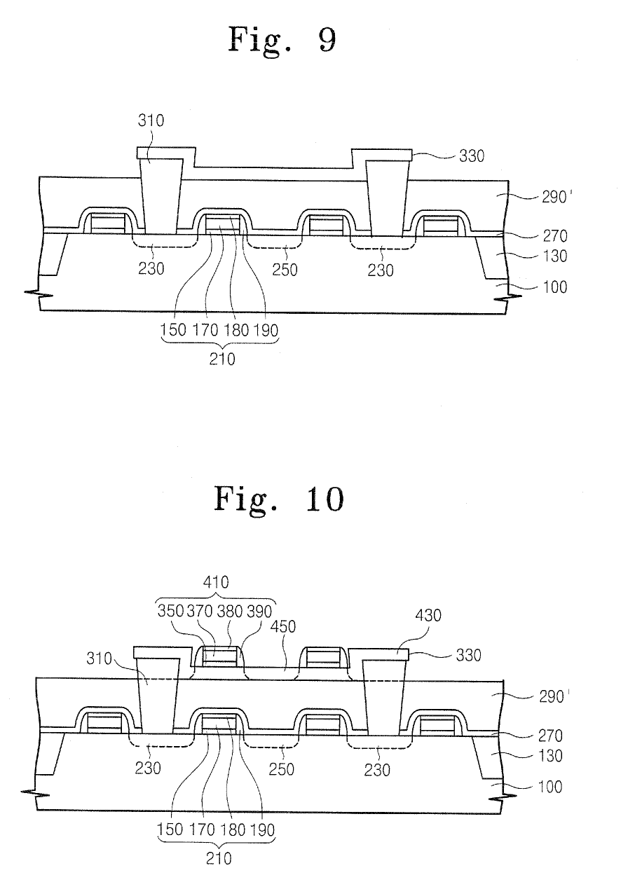

Referring to FIG. 9, a semiconductor layer pattern 330 for channel formation is formed on the recessed first interlayer insulation layer pattern 290′. At this point, the semiconductor layer pattern 330 may extend from the protruded region 310a of the epitaxial plug 310. The semiconductor layer pattern 330 is formed on the first interlayer insulation layer pattern 290′ between the protruding epitaxial plugs 310. The semiconductor layer pattern 330 may be formed on one sidewall and the top of the protruding region 310a of epitaxial plugs 310, thereby forming a recessed structure.

More specifically, an amorphous silicon layer is formed on the first interlayer insulation layer pattern 290′ having the protruding epitaxial plug 310. A heat treatment process is then performed on the amorphous silicon layer to crystallize the amorphous silicon layer using the epitaxial plug 310, having a single crystalline structure, as a seed. The crystallization temperature may be between about 500 and about 800° C. The crystallization time may be between about 8 and about 15 hours. Preferably, the crystallization may be performed at about 600° C. for about 12 hours. After the heat treatment process the semiconductor layer pattern 330 may be a single crystalline layer or a poly crystalline layer with large grain size.

Referring to FIG. 10, thin film transistors 410 are formed on the recessed region of the semiconductor layer pattern 330. The thin film transistor 410 may include a gate insulation layer 350, a gate electrode 370, an insulation layer pattern 380, a spacer 390, a source region 450, and a drain region 430. The source region 450 and the drain region 430 are formed using an ion implantation process on the semiconductor layer pattern 330 on both sides of the thin film transistor 410 and may be referred to as impurity regions. The epitaxial plugs 310 may contact respectively opposite impurity regions of the thin film transistors 410. In other words, one epitaxial plug 310 may contact a drain region 430 of a first thin film transistor 410 and another epitaxial plug 310 may contact a drain region 430 of an adjacent thin film transistor 410. The drain region 430 may extend from one side of the gate electrode 370 in the thin film transistor 410, and have a structure protruding higher above the first interlayer insulation layer pattern 290′ than that of the source region 450. Therefore, compared to the conventional art, a relatively larger impurity region may be formed.

The semiconductor layer pattern 330 is formed along the protruding region of the epitaxial plug 310 such that the thickness becomes larger than the conventional art. Accordingly, cutting or thinning of the semiconductor layer patter 330 can be prevented and the region of the semiconductor layer pattern 330 contacting the epitaxial plug 310 increases; making it advantageous for crystallization. Additionally, because of the protruding structure, the source region 450 and the drain region 430 are asymmetrically formed, thereby minimizing the leakage current of the stacked thin film transistor.

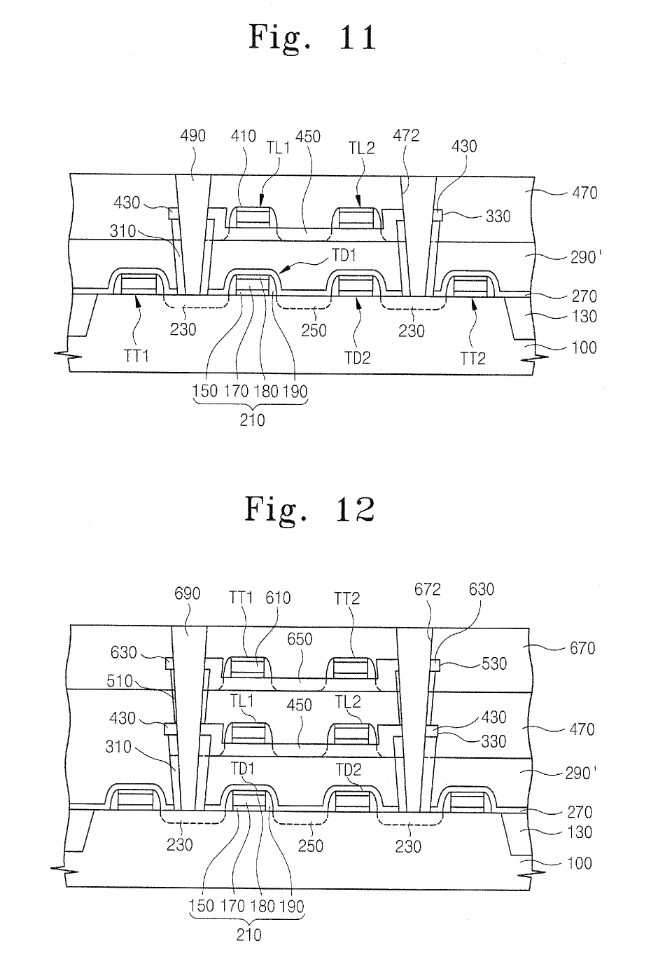

Referring to FIG. 11, a second interlayer insulation layer 470 is formed over the thin film transistors 410. A contact hole 472 for a node contact metal plug is formed by penetrating the second interlayer insulation layer 470, the drain region 430 of the thin film transistor 410, and the epitaxial plug 310 to expose the source region 230 of the bulk transistor 210. A conductive layer, e.g., a metal layer such as tungsten is formed to fill the contact hole 472 such that a node contact plug, e.g., a node contact metal plug 490 is formed. The node contact metal plug 490 may further include a barrier metal. The barrier metal may include titanium or titanium nitride. Accordingly, even if silicon sucking in a region adjacent to the node contact metal plug 490 occurs, the cutting and thinning of the semiconductor layer pattern 330 for channel formation can be prevented. Moreover, since the contacting area of the node contact metal plug 490 and the drain region 430 increases, increases in contact resistivity due to silicon sucking and silicide formation can be prevented.

The semiconductor device manufactured as described above may be a DRAM having a capacitor, a non-volatile memory including a gate electrode with a charge trap layer or a floating gate electrode, or an SRAM. Referring to FIG. 11, the bulk transistors 210 may include transfer transistors TT1 and TT2, and drive transistors TD1 and TD2 of an SRAM cell. The thin film transistors 410 may be load transistors TL1 and TL2 of an SRAM cell.

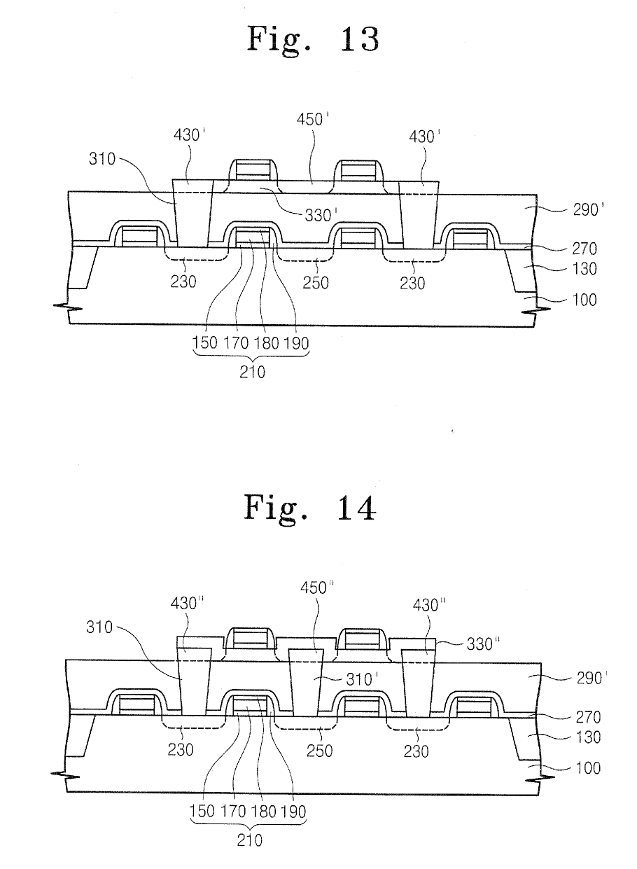

FIG. 12 is a cross-sectional view of a modified first embodiment. Referring to FIG. 12, the transfer transistors TT1 and TT2 are stacked on the load transistors TL1 and TL2.

Referring to FIGS. 10 and 12, a method for manufacturing a semiconductor device according to a modified embodiment of the invention will be described.

The second interlayer insulation layer 470 is formed on an entire surface of the semiconductor substrate 100 having the first thin film transistor 410. A contact hole is formed by penetrating the second interlayer insulation layer 470 to expose the source region 430 of the first thin film transistor 410. A second epitaxial plug 510 is formed on the contact hole. The second epitaxial plug 510 is formed using a process similar to that of the first epitaxial plug 310 of FIG. 7. The second interlayer insulation layer 470 is recessed in a predetermined thickness such that the second epitaxial plug 510 protrudes from the second interlayer insulation layer 470. Using the same method in FIGS. 8 through 10, a second semiconductor layer pattern 530 for channel formation is formed, and second thin film transistors 610 are formed on the second semiconductor layer pattern 530. The second thin film transistor 610 has a structure similar to that of the first thin film transistor 410, and includes a gate insulation layer, a gate electrode, an insulation layer pattern, a spacer, a source region 630 and a drain region 650.

A third interlayer insulation layer 670 is formed on an entire surface of the semiconductor substrate 100 having the second thin film transistors 610. A contact hole 672 for a node contact metal plug is formed by penetrating a source region 630 of the second thin film transistor 610, the second interlayer insulation layer 470 (and/or the second epitaxial plug 510), the drain region 430 of the first thin film transistor 410, and the first epitaxial plug 310 to expose the source region 230 of the bulk transistor 210. A node contact metal plug 690 is formed using a metal layer such as tungsten to fill the contact hole. The node contact metal plug 690 may include a barrier metal. The barrier metal may be formed of a titanium or titanium nitride layer.

The invention is not limited to this configuration, and the transistors of FIG. 12 can be arranged differently. That is, the position of the load transistor and the transfer transistor can be interchangeable and the drive transistor may be formed of the thin film transistor.

FIG. 13 is a cross-sectional view illustrating a method of manufacturing a semiconductor device having a stacked transistor according to a second embodiment of the invention.

Referring to FIG. 13, a semiconductor layer pattern 330 for channel formation is formed on a first interlayer insulation layer pattern 290′ between the protruding epitaxial plugs 310. The thickness of the semiconductor layer pattern 330′ may be approximately the same as the protruding height of the epitaxial plug 310. The structure of this embodiment may be combined with the modified embodiment of FIG. 12 described above.

A method for manufacturing the structure will be described. In the process of FIG. 9, a semiconductor layer pattern 330 for channel formation is formed as high as the protruding height of the epitaxial plug 310 and then planarized. To perform the planarization process, a mold layer is additionally formed on the recess structure of the semiconductor layer pattern 330 for the channel formation, and then a chemical mechanical polishing (CMP) process can be performed. The following process is performed similar to that of FIG. 10 to form a source region 450′ and a drain region 430′. Then, a node contact metal plug similar to that shown in FIG. 11 may be formed.

FIG. 14 is a cross-sectional view illustrating a method of manufacturing a semiconductor device having a stacked transistor according to a third embodiment of the invention.

Referring to FIG. 14, an additionally-added protruding epitaxial plug 310′ may be disposed between the protruding epitaxial plugs 310, and also be connected to the drain region 250 of the bulk transistor. The additionally-added protruding epitaxial plug 310′ is formed using a process similar to that of the protruding epitaxial plug 310. Accordingly, a semiconductor layer pattern 330″ for channel formation extends over the top of the additionally-added protruding epitaxial plug 310′. The following process is performed similar to that of FIG. 10 to form a source region 450″ and a drain region 430″. Then, a node contact metal plug similar to that shown in FIG. 11 may be formed. The source region 450″ and the drain region 430″ have a protruding structure. Accordingly, compared to the conventional art, a larger impurity region can be obtained. The structure of this embodiment may be combined with the modified embodiment of FIG. 12 described above.

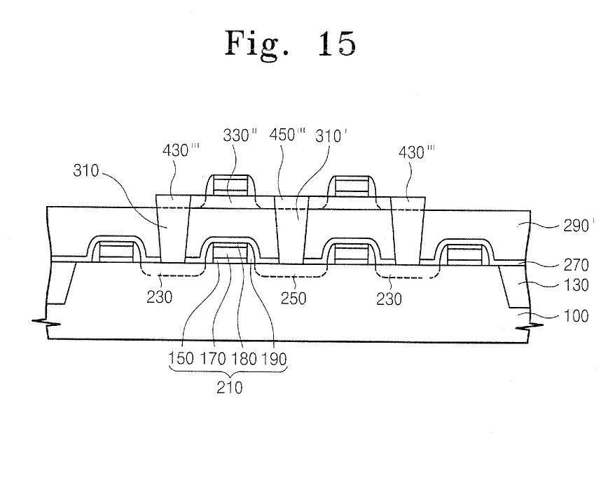

FIG. 15 is a cross-sectional view illustrating a method of manufacturing a semiconductor device having a stacked transistor according to a fourth embodiment of the invention.

This embodiment has a combined structure of the second embodiment and the third embodiment. Referring to FIG. 15, the semiconductor layer pattern 330″ for channel formation is formed on the first interlayer insulation layer pattern 290′ between three protruding epitaxial plugs 310, 310′. The semiconductor layer pattern 330″ may be formed using a process similar to that of the semiconductor layer pattern 330. The thickness of the semiconductor layer pattern 330″ may be approximately the same as the protruding height of the epitaxial plug 310′. The semiconductor layer pattern 330″ may be formed at least as high as the protruding height of the epitaxial plugs 310, 310′, and then may be planarized. To perform the planarization process, a mold layer is additionally formed on the recess structure of the semiconductor layer pattern 330″, and then a CMP process can be performed. The following process is performed similar to that of FIG. 10 to form a source region 450′″ and a drain region 430′″. Then, a node contact metal plug similar to that shown in FIG. 11 may be formed. The structure of this embodiment may be combined with the modified embodiment of FIG. 12 described above.

According to the invention, since the contact region of the epitaxial plug and the semiconductor layer pattern increases, crystallization of the thin layer for the channel formation can be improved. The cutting and thinning of the semiconductor layer pattern for channel formation due to the silicon atom transfer and silicon sucking during the crystallization process can be prevented. Additionally, since a contact region of the semiconductor layer pattern for channel formation and the node contact metal plug increases, the contact resistance characteristics of the interface can be improved. Because of the source and drain regions having an asymmetric structure due to the protruding impurity region, a leakage current can be reduced as well.

The invention provides a semiconductor device including a stacked transistor with a thin film transistor structure in which at least one impurity region protrudes. A thin layer for channel formation may be a single crystalline structure or a poly crystalline structure with a large size grain.

In embodiments of the invention, the thin film transistors may be a stacked structure with at least one layer.

In other embodiments of the invention, the thin film transistor may have impurity regions protruding higher than the bottom of both sides of the thin film transistor. The epitaxial plug may protrude respectively on the bottoms of the protruded impurity regions.

In still other embodiments of the invention, the semiconductor layer pattern for channel formation may have a height at least as high as a protruding height of the epitaxial plug.

The invention also provides a semiconductor device manufacturing method for different structures of each embodiment.

The above-disclosed subject matter is to be considered illustrative, and not restrictive, and the appended claims are intended to cover all such modifications, enhancements, and other embodiments, which fall within the true spirit and scope of the invention. Thus, to the maximum extent allowed by law, the scope of the invention is to be determined by the broadest permissible interpretation of the following claims and their equivalents, and shall not be restricted or limited by the foregoing detailed description.

What is claimed is:

1. A semiconductor device having stacked transistors, comprising:
a bulk transistor formed on a semiconductor substrate, the bulk transistor having first impurity regions;
a first interlayer insulation layer overlying the bulk transistor;
a semiconductor layer pattern on the first interlayer insulation layer; and
a thin film transistor formed on the semiconductor layer pattern, the thin film transistor having second impurity regions, at least one of the second impurity regions protruding higher above the first interlayer insulation layer than another second impurity region.

2. The semiconductor device of claim 1, further comprising an epitaxial plug disposed between the protruding second impurity region and at least one of the first impurity regions through the first interlayer insulation layer.

3. The semiconductor device of claim 2, wherein a top portion of the epitaxial plug protrudes above a top surface of the first interlayer insulation layer.

4. The semiconductor device of claim 3, further comprising a node contact plug disposed to penetrate the epitaxial plug and the protruding second impurity region to electrically connect the at least one first impurity region of the bulk transistor and the protruding second impurity region.

5. A semiconductor device having stacked transistors, comprising:
bulk transistors formed on a semiconductor substrate, the bulk transistors having first impurity regions;
a first interlayer insulation layer formed on the semiconductor substrate having the bulk transistors;
first epitaxial plugs connected to respectively opposite first impurity regions of adjacent bulk transistors through the first interlayer insulation layer, and having top portions that protrude from the surface of the first interlayer insulation layer;
a semiconductor layer pattern formed on the first interlayer insulation layer and contacting the first epitaxial plugs; and
thin film transistors formed on the semiconductor layer pattern, and having second impurity regions.

6. The semiconductor device of claim 5, wherein the first epitaxial plugs are connected to respectively opposite second impurity regions of adjacent thin film transistors, and the semiconductor layer pattern extends over the first epitaxial plugs.

7. The semiconductor device of claim 6, wherein the respectively opposite second impurity regions protrude at least as high above the first interlayer insulation layer as the top portions of the first epitaxial plugs.

8. The semiconductor device of claim 5, further comprising a second epitaxial plug connected to at least one of the first impurity regions between adjacent bulk transistors through the first interlayer insulation layer, the second epitaxial plug having a top portion that protrudes from the surface of the first interlayer insulation layer.

9. The semiconductor device of claim 8, wherein the second epitaxial plug is connected to at least one of the second impurity regions between adjacent thin film transistors, and the semiconductor layer pattern extends over the second epitaxial plug.

10. The semiconductor device of claim 9, wherein the at least one second impurity region between adjacent thin film transistors protrudes at least as high above the first interlayer insulation layer as the top portion of the second epitaxial plug.

11. The semiconductor device of claim 5, wherein the semiconductor layer pattern is formed between the first epitaxial plugs, and is at least as thick as the top portions of the first epitaxial plugs protruded above the first interlayer insulation layer.

12. The semiconductor device of claim 5, further comprising node contact plugs penetrating the first epitaxial plugs and the first interlayer insulation layer to electrically connect to the respectively opposite first impurity regions of the adjacent bulk transistors.

13. A semiconductor device having stacked transistors, comprising:
bulk transistors disposed on a semiconductor substrate, the bulk transistors having first impurity regions;
a first interlayer insulation layer overlying the bulk transistors;
first epitaxial plugs connected to respectively opposite first impurity regions of adjacent bulk transistors through the first interlayer insulation layer, and having top portions that protrude from the surface of the first interlayer insulation layer;
a first semiconductor layer pattern disposed on the first interlayer insulation layer and contacting the first epitaxial plugs;
first thin film transistors disposed on the first semiconductor layer pattern, and having second impurity regions disposed on both sides thereof;
a second interlayer insulation layer disposed on the semiconductor substrate and the first thin film transistors;
second epitaxial plugs connected to respectively opposite second impurity regions of adjacent first thin film transistors through the second interlayer insulation layer, and having top portions that protrude from the surface of the second interlayer insulation layer;
a second semiconductor layer pattern disposed on the second interlayer insulation layer and contacting the second epitaxial plugs; and
second thin film transistors disposed on the second semiconductor layer pattern, and having third impurity regions disposed on both sides thereof.

14. The semiconductor device of claim 13, further comprising:
a third interlayer insulation layer; and
node contact plugs, the node contact plugs disposed to penetrate the third interlayer insulation layer, the second semiconductor layer pattern, the second epitaxial plugs, the first semiconductor layer pattern, and the first epitaxial plugs.

15. A method for manufacturing a semiconductor device having stacked transistors, the method comprising:
forming bulk transistors on a semiconductor substrate, the bulk transistors having first impurity regions;
forming a first interlayer insulation layer overlying the bulk transistors;
selectively etching the first interlayer insulation layer to form at least one contact hole exposing at least one of the first impurity regions;
forming at least one first epitaxial plug filling the at least one contact hole;
removing an upper portion of the first interlayer insulation layer to protrude the top portion of the at least one first epitaxial plug above the top surface of a remaining portion of the first interlayer insulation layer;
forming a semiconductor layer pattern on the first interlayer insulation layer and contacting the at least one first epitaxial plug; and
forming first thin film transistors on the semiconductor layer pattern, the first thin film transistors having second impurity regions.

16. The method of claim 15, wherein the semiconductor layer pattern extends over the first epitaxial plug.

17. The method of claim 16, wherein at least one of the second impurity regions protrudes at least as high above the top surface of the first interlayer insulation layer as the top portion of the first epitaxial plug.

18. The method of claim 16, further comprising:
forming a second interlayer insulation layer overlying the first thin film transistors; and
forming at least one node contact plug penetrating the second interlayer insulation layer, the semiconductor layer pattern, and the first epitaxial plug to connect at least one of the second impurity regions to at least one of the first impurity regions.

19. The method of claim 15, wherein the semiconductor layer pattern is formed between two first epitaxial plugs, and protrudes at least as high above the first interlayer insulation layer as the top portion of the two first epitaxial plugs.

20. The method of claim 15, further comprising:
forming a second interlayer insulation layer overlying the first thin film transistors; and
forming second thin film transistors on the second interlayer insulation layer.

21. The method of claim 15, further comprising forming a second epitaxial plug protruding between adjacent bulk transistors.

22. The method of claim 15, wherein forming the at least one first epitaxial plug comprises:
forming a sacrificial layer on the first interlayer insulation layer, the sacrificial layer having an etch rate different from that of the first interlayer insulation layer; and
removing the sacrificial layer.

23. The method of claim 22, wherein the sacrificial layer is formed of a material selected from the group consisting of SiN, SiON, and a combination thereof.

24. The method of claim 15, wherein forming the semiconductor layer pattern comprises:
forming an amorphous silicon layer on the first interlayer insulation layer having the at least one protruded first epitaxial plug;
performing a heat treatment on the amorphous silicon layer to form a crystallized silicon layer; and
patterning the crystallized silicon layer.

25. The method of claim 24, further comprising removing the crystallized silicon layer over the protruded epitaxial plug.

26. The method of claim 15, wherein the first epitaxial plug and the semiconductor layer pattern include silicon.
